(19) United States
(12) Patent Application Publication
(10) Pub. No.: US 2020/0105481 A1
(43) Pub. Date: Apr. 2, 2020

(54) HETEROJUNCTION PEROVSKITE SOLAR CELL WITH HIGH STABILIZED EFFICIENCY AND LOW VOLTAGE LOSS

(71) Applicant: MASSACHUSETTS INSTITUTE OF TECHNOLOGY, Cambridge, MA (US)

(72) Inventors: Moungi G. Bawendi, Cambridge, MA (US); Jason Yoo, Cambridge, MA (US); Seongsik Shin, Cambridge, MA (US)

(73) Assignee: MASSACHUSETTS INSTITUTE OF TECHNOLOGY, Cambridge, MA (US)

(21) Appl. No.: 16/590,315

(22) Filed: Oct. 1, 2019

Related U.S. Application Data
(60) Provisional application No. 62/739,824, filed on Oct. 1, 2018.

(51) Int. Cl. H01G 9/20; H01L 51/00; H01L 51/42; H01L 51/44; H01G 9/00

(52) U.S. Cl. CPC H01G 9/2009; H01L 51/0007; H01L 51/4253; H01L 51/0077; H01L 51/448; H01G 9/0036; H01G 9/2018; H01L 51/441

(57) ABSTRACT

A photovoltaic device and method of manufacturing the device are described.

### CLAIM OF PRIORITY

This application claims priority to U.S. Provisional Patent No. 62/739,824, filed Oct. 1, 2018, which is incorporated by reference in its entirety.

### FEDERAL SPONSORSHIP

This invention was made with Government Support under Grant No. NNX16AM70H awarded by the NASA Goddard Space Flight Center, and Grant No. W911NF-13-D-0001 awarded by the U.S. Army Research Office. The Government has certain rights in the invention.

### FIELD OF THE INVENTION

The invention relates to perovskite solar cells.

### BACKGROUND

Organic-inorganic hybrid perovskites are seeing an unprecedented growth in research due to their suitable optoelectronic properties for solar cell applications. In addition, perovskite solar cells (PSCs) have attractive qualities for commercialization, as they can be fabricated to be light weight, low cost, and solution processed. In less than 10 years of active research, PSCs have reached power conversion efficiencies (PCEs) that are comparable to other competing thin film technologies, such as Copper Indium Gallium Selenide and Cadmium Telluride. However, while state of the art PCSs can deliver impressive PCEs, this comes with a low stability that many consider unacceptable for real world applications.

### SUMMARY

In general, a method of manufacturing a photovoltaic device structure can include coating a perovskite precursor in a solvent on a semiconductor substrate, the precursor forming a layer on surface of the semiconductor substrate.

In another aspect, a photovoltaic device can include a hole transport layer adjacent to a first electrode, an electron transport layer adjacent to a second electrode, a perovskite layer between the hole transport layer and the electron transport layer, and a passivating layer between the perovskite layer and the hole transporting layer.

In certain circumstances, the layer can be a 2D perovskite layer.

In certain circumstances, the semiconductor can include a 3D perovskite on an electrode layer.

In certain circumstances, the precursor can include a C2-C16 alkyl ammonium halide.

In certain circumstances, the C2-C16 alkyl ammonium can be a C4 alkyl ammonium, C5 alkyl ammonium, C6 alkyl ammonium, C7 alkyl ammonium, C8 alkyl ammonium, C10 alkyl ammonium, C12 alkyl ammonium, C14 alkyl ammonium, or C16 alkyl ammonium.

In certain circumstances, the halide can be a bromide or iodide.

In certain circumstances, the perovskite precursor can include a lead iodide.

In certain circumstances, the solvent can be chloroform.

In certain circumstances, coating can include spin-coating, ink-jet printing, roll-to-roll printing, or blade coating. In certain circumstances, coating can include spin coating at a rate between 2000 and 6000 rpm, for example, at 2500, 3000, 3500, 4000, 4500, 5000 or 5500 rpm.

In certain circumstances, the C2-C16 alkyl ammonium can be n-Butylammonium bromide (C4Br), n-Hexylammonium bromide (C6Br), or n-Octylammonium bromide (C8Br), the solvent can be chloroform and the 2D perovskite can be lead iodide.

In certain circumstances, the passivating layer can include a 2D perovskite layer.

In certain circumstances, the 2D perovskite layer can include a C2-C16 alkyl ammonium group.

In certain circumstances, the device can be made by a method described herein.

In certain circumstances, the device can have a power conversion efficiency of over 23%.

Other aspects, embodiments, and features will be apparent from the following description, the drawings, and the claims.

### BRIEF DESCRIPTION OF DRAWINGS

FIGS. 1A-1F depict data showing the effect of the SPD strategy on 3D/2D perovskite fabrication.

FIGS. 2A-2D depict characterization of 3D control and 3D/2D perovskites.

FIGS. 3A-3C depict PSC device characterization.

FIGS. 4A-4D depict stabilization measurements of 3D/2D PSCs.

FIGS. 5A-5B depict the effect of IPA and CF on 3D perovskite and on the formation of 3D/2D perovskites.

FIGS. 6A-6B depict XRD and GIXRD pattern for the 3D control and three different 3D/2D perovskite samples.

FIGS. 7A-7B depict AFM and KPFM result on 3D and 3D/2D perovskite substrates.

FIGS. 8A-8E depict lifetime measurement on 3D and 3D/2D perovskites.

FIGS. 9A-9F depict UPS measurement results and schematic illustration of band alignments for 3D and 3D/2D perovskite samples.

FIGS. 10A-10B depict hysteresis and summary of 3D and 3D/2D PSC device performance.

FIGS. 11A-11C depict device stability and humidity resistance of 3D and 3D/2D PSCs and perovskite films.

FIG. 12 depicts certification of 3D/2D PSC with stabilized J-V curve tested at an independent and accredited PV testing lab.

FIGS. 13A-13C depict extended stabilization measurement and MPP measurement on 3D/2D PSCs.

FIGS. 14A-14B depict an absorption spectrum and EQE spectrum of the PSCs.

FIGS. 15 and 16 depict photovoltaics.

FIG. 17 depicts performance criteria of a device.

### DETAILED DESCRIPTION

A selective precursor dissolution (SPD) strategy can result in a novel layered perovskite solar cell, which results in a substantial increase in stability while retaining record setting efficiencies. In the process a thin 2D perovskite layer is grown on top of a bulk (3D) thin film perovskite cell where the solvent used for the 2D perovskite deposition selectively dissolves the 2D perovskite precursor, while retaining the high quality 3D perovskite underlayer. This strategy maximizes and stabilizes device performance by preventing the formation of a detrimental crystallographic δ-phase during surface treatment. This detrimental crystal phase has been observed using conventional synthetic methods and results in a loss of efficiency. The strategy also effectively passivates surface and grain boundary defects, minimizing non-radiative recombination sites, and preventing carrier quenching at the perovskite interface. This results in an unprecedentedly low open-circuit-voltage loss of ˜340 mV and a record certified stabilized PCE of 22.6% with enhanced operational stability. In addition, this method can be applied to other surface treatments to improve and stabilize device performance. Up to now, all studies have focused on the structure and the identity of the 2D perovskite materials. The synthetic method can be the most critical factor for fabricating high performance 3D/2D perovskite solar cells with high operational stability; something that has not been investigated and has been overlooked. The novel PSCs were able to maintain high efficiency (>20%) under maximum power point tracking for >200 hrs under full AM 1.5 G illumination, including the ultraviolet, without incorporation of Cesium and Rubidium additives. This indicates that the finding can be a breakthrough in 2D perovskite materials and advance the perovskite field as a whole. In addition, the SPD strategy allows scale-up production of heterojunction PSCs, which has not been demonstrated due to poor solvent compatibility during PSC fabrication.

Adding a wide bandgap 2-dimensional (2D) perovskite layer onto a lead halide perovskite thin film can effectively passivate surface and grain boundary defects in lead halide perovskite solar cells (PSCs), increasing device performance and stability. See, Cho, Y. et al. Mixed 3D-2D Passivation Treatment for Mixed-Cation Lead Mixed-Halide Perovskite Solar Cells for Higher Efficiency and Better Stability. Adv. Energy Mater. 1703392 (2018). doi:10.1002/aenm.201703392, which is incorporated by reference in its entirety. However, despite the potentially attractive qualities of 2D perovskite interlayers, the conventional 2D perovskite synthesis process has not demonstrated that 3D/2D heterojunction PSCs are superior to the record-performing single junction 3D PSCs. See, National Renewable Energy Laboratory, Best Research-Cell Efficiencies chart; https://www.nrel.gov/pv/assets/images/efficiency-chart.png, which is incorporated by reference in its entirety. Here, a selective precursor dissolution (SPD) strategy in which the solvent can be used for the 2D perovskite deposition selectively dissolves the 2D perovskite precursor, while retaining the high quality 3D perovskite underlayer. This strategy maximizes and stabilizes device performance by preventing the formation of the detrimental crystallographic δ-phase during surface treatment, which has been observed using conventional synthetic methods. The strategy also effectively passivates surface and grain boundary defects, minimizing non-radiative recombination sites, and preventing carrier quenching at the perovskite interface. This results in an unprecedentedly low open-circuit-voltage loss of ˜340 mV and a record certified stabilized power conversion efficiency (PCE) of 22.6% with enhanced operational stability.

PSCs have been intensively studied in the last few years owing to their excellent photovoltaic performance and low fabrication costs. See, Snaith, H. J. Present status and future prospects of perovskite photovoltaics. Nat. Mater. 17, 372-376 (2018), Park, N.-G., Gratzel, M., Miyasaka, T., Zhu, K. & Emery, K. Towards stable and commercially available perovskite solar cells. Nat. Energy 1, 16152 (2016), and Correa-Baena, J.-P. et al. Promises and challenges of perovskite solar cells. Science 358, 739-744 (2017), each of which is incorporated by reference in its entirety. Recent progress on defect management and interface engineering has resulted in devices with PCEs exceeding 20%, with stability maintained even at elevated temperatures. Further improvements can be gained through interlayer/surface engineering to passivate defects by using metal oxides, polymers/small molecules, or organic halides. See, Yang, W. S. et al. Iodide management in formamidinium-lead-halide-based perovskite layers for efficient solar cells. Science 356, 1376-1379 (2017), Tan, H. et al. Efficient and stable solution-processed planar perovskite solar cells via contact passivation. Science 355, 722-726 (2017), Abdi-Jalebi, M. et al. Maximizing and stabilizing luminescence from halide perovskites with potassium passivation. Nature 555, 497-501 (2018), Shin, S. S. et al. Colloidally prepared La-doped BaSnO3 electrodes for efficient, photostable perovskite solar cells. Science 356, 167-171 (2017), Saliba, M. et al. Incorporation of rubidium cations into perovskite solar cells improves photovoltaic performance. Science 354, 206-209 (2016), Shao, Y., Xiao, Z., Bi, C., Yuan, Y. & Huang, J. Origin and elimination of photocurrent hysteresis by fullerene passivation in CH₃NH₃PbI₃ planar heterojunction solar cells. Nat. Commun. 5, 5784 (2014), Han, G. S. et al. Retarding charge recombination in perovskite solar cells using ultrathin MgO-coated TiO2 nanoparticulate films. J. Mater. Chem. A 3, 9160-9164 (2015), Lin, Y. et al. Enhanced Thermal Stability in Perovskite Solar Cells by Assembling 2D/3D Stacking Structures. J. Phys. Chem. Lett. 9, 654-658 (2018), and Zheng, X. et al. Defect passivation in hybrid perovskite solar cells using quaternary ammonium halide anions and cations. Nat. Energy 2, 17102 (2017), each of which is incorporated by reference in its entirety. Among surface-based approaches, the in-situ preparation of surface-bound 2D perovskites on a 3D perovskite (thereby forming a 3D/2D structure) has gained attention for its ability to effectively passivate interfaces and grain boundary defects, and increase moisture resistance. Despite these attractive properties, the efficiency of the best 3D/2D heterojunction PSCs (˜21%) has lagged behind that of single junction 3D PSCs (˜22%). One potential reason for this efficiency gap has been the formation of the photo-inactive perovskite δ-phase upon surface treatment, preventing the realization of the full potential of the 3D/2D PSCs. Key challenges in the fabrication of 3D/2D PSCs with high PCE and operational stability are maintaining the underlying 3D perovskite layer pristine during surface treatment, and minimizing interlayer carrier quenching.

For example, a perovskite PV technology can combine high efficiency, long term stability, and scalability beyond current state-of-the-art by developing solution processable materials for carrier generation and extraction, defect passivation, and through a microscopic understanding of the effects of non-uniformity on device performance and stability.
Scaled up production of light-weight and large area perovskite PVs can be achieved due to novel low-temperature and solution processable layers.
Multi junction tandem PVs (all-perovskite and perovskite/Si) can be achieved with efficiencies beyond silicon PVs.
Easily deployable and high power-to-weight ratio perovskite PVs for local and remote applications

A SPD strategy for the in-situ synthesis of a 2D perovskite film onto an underlying 3D perovskite film can lead to an effective synthesis of various 2D perovskites onto 3D perovskite films, maximizing device performance and stability. This strategy prolongs carrier lifetime through defect passivation and, remarkably, improves the open circuit voltage (V_{OC}), resulting in PCEs over 23%. Through this strategy, a reverse PCE of 23.4% was obtained, and 23.2% at an accredited photovoltaic testing laboratory. Additionally, a stabilized PCE (measured under stabilized conditions for ˜31 min.) of 22.6% was achieved for the best-performing PSC—the highest stabilized and certified PCE reported for PSCs thus far—with a V_{OC} loss of ˜340 mV, which is the lowest reported thus far, and with enhanced operational stability.

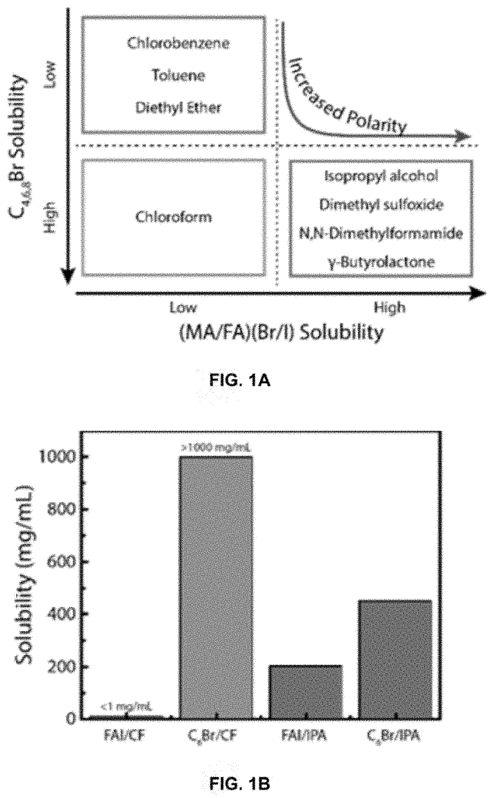

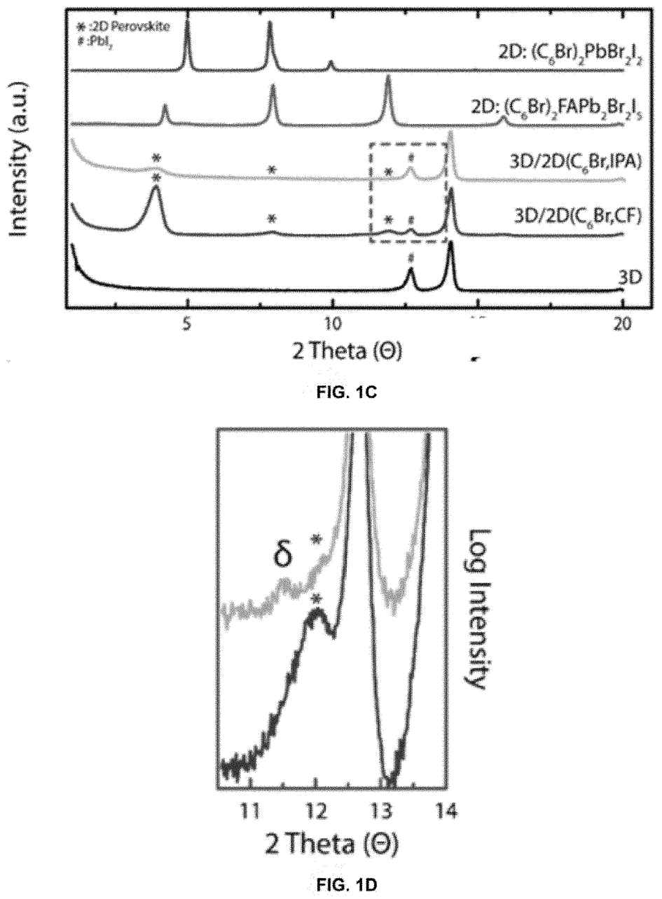

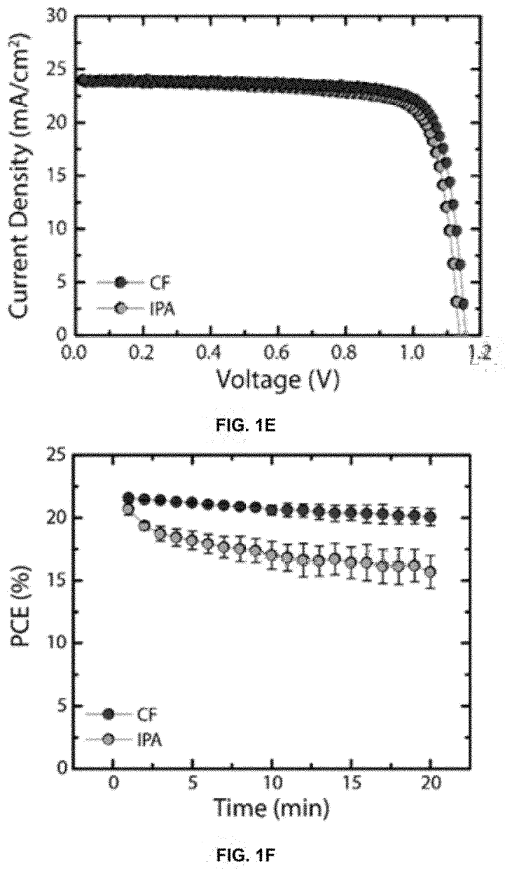

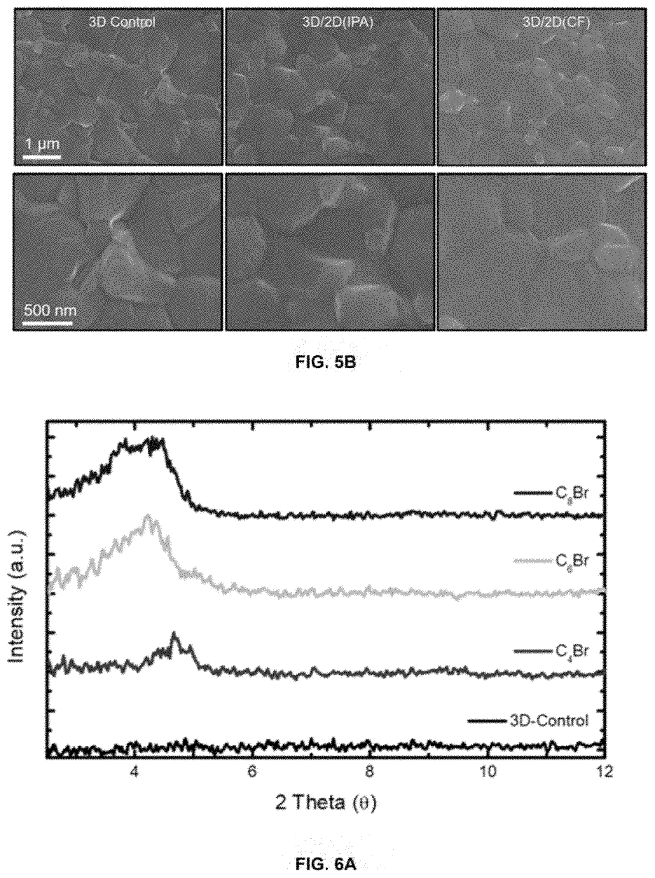

Since the choice of solvent is critical to obtaining high quality perovskite films, optimal solvent choices were explored for the 2D perovskite treatment by performing a preliminary screening test for solvents with varying polarities. FIG. 1A describes the solubility of alkylammonium-based 2D perovskite precursors and 3D perovskite precursors (MA/FA-Br/I) in various solvents. Most solvents with low polarity poorly dissolve perovskite precursors and are often used as an anti-solvent to obtain compact perovskite films. See, Jeon, N. J. et al. Solvent engineering for high-performance inorganic-organic hybrid perovskite solar cells. Nat. Mater. 13, 897-903 (2014), which is incorporated by reference in its entirety. Interestingly, chloroform (CF), despite a relative low polarity, can effectively solubilize long-chain 2D perovskite precursors. On the other hand, solvents with high polarity (isopropyl alcohol (IPA), dimethyl sulfoxide, N,N-dimethylformamide, γ-butyrolactone) readily solubilize all perovskite precursors regardless of chain length. Most reported in-situ syntheses of 2D perovskites onto 3D perovskite films have been performed using IPA. IPA effectively dissolves the 3D precursors owing to its highly polar nature and its ability to hydrogen bond, which can negatively affect the underlying 3D perovskite film. In addition, the hygroscopic nature of IPA results in the rapid absorption of water when exposed to ambient air, where dissolved water can negatively impact device performance. See, Yao, K. et al. A copper-doped nickel oxide bilayer for enhancing efficiency and stability of hysteresis-free inverted mesoporous perovskite solar cells. Nano Energy 40, 155-162 (2017), which is incorporated by reference in its entirety. The solubility of the 3D and 2D perovskite precursors was compared (FAI and n-hexylammonium bromide (C₆Br)) in IPA and CF (FIG. 1B). IPA effectively dissolves both FAI and C₆Br, with solubilities in excess of 200 mg/mL. However, FAI has very limited solubility in CF whereas the solubility of C₆Br in CF is twice that in IPA. The solubility of the 3D perovskite in IPA indicates that the chemical composition and crystallinity of the underlying 3D perovskite film can be negatively impacted when IPA is used as a solvent for 2D perovskite treatment. On the other hand, 3D perovskites are insoluble in CF, making it a benign and ideal solvent for surface treatments (FIG. 5A).

An improved 3D/2D interface quality is supported by X-ray diffraction (XRD) measurements. FIG. 1C shows XRD results for the 3D perovskite, the 3D perovskite treated with the 2D perovskite with CF or IPA as solvents and C₆Br as the 2D precursor (3D/2D(C₆Br,CF) or 3D/2D (C₆Br,IPA)), and pristine 2D perovskites. Compared to the 3D perovskite, 3D/2D perovskites with C₆Br treatment have additional peaks at 3.9°, 7.9°, and 11.9° (marked with *) and show a lower peak intensity for the PbI₂ peak (marked with #), indicating the incorporation of near-surface PbI₂ into the 2D perovskite during the in-situ synthesis of the 2D perovskite. When comparing XRD peaks from pristine 2D perovskite films, the 2D perovskite peaks from 3D/2D structures matches well with the Ruddlesden-Popper hybrid perovskite (C₆Br)₂(FA)Pb₂Br₂I₅ compared to (C₆Br)₂PbBr₂I₂. Indeed in the case of alkyl ammonium halide precursors, the formation of (C₆Br)2(FA or MA)Pb₂Br₂I₅ is favored over (C₆Br)₂PbBr₂I₂. See, Lin, Y. et al. Enhanced Thermal Stability in Perovskite Solar Cells by Assembling 2D/3D Stacking Structures. J. Phys. Chem. Lett. 9, 654-658 (2018), which is incorporated by reference in its entirety. The slight shift in the lower angle peaks can be attributed to varying cation or halide stoichiometries, and/or different thicknesses for the crystal layers in the 2D perovskite (the n value). See, Gélvez-Rueda, M. C. et al. Interconversion between Free Charges and Bound Excitons in 2D Hybrid Lead Halide Perovskites. J. Phys. Chem. C 121, 26566-26574 (2017), Jung, M., Shin, T. J., Seo, J., Kim, G. & Seok, S. Il. Structural features and their functions in surfactant-armoured methylammonium lead iodide perovskites for highly efficient and stable solar cells. Energy Environ. Sci. (2018). doi:10.1039/C8EE00995C, and Hassan, Y. et al. Structure-Tuned Lead Halide Perovskite Nanocrystals. Adv. Mater. 28, 566-573 (2016), each of which is incorporated by reference in its entirety. In addition, the 2D perovskite peak intensities from 3D/2D perovskites fabricated using CF (3D/2D (C₆Br, CF)) are noticeably stronger than those from 3D/2D perovskites fabricated using IPA (3D/2D (C₆Br, IPA)), and show a lower signal intensity from PbI₂. This suggests that in-situ 2D perovskite synthesis on 3D perovskites is more effective when using CF as the solvent. Additionally, scanning electron microscope (SEM) images show less faceted and less distinctive grain surfaces and grain boundaries for the 3D/2D (C₆Br, CF) compared to the 3D perovskite (3D control) and the 3D/2D (C₆Br, IPA), further supporting the effectiveness of in-situ 2D perovskite synthesis using CF as the solvent (FIG. 5B). Finally, XRD reveals formation of non-perovskite polymorphs of FAPbI₃ (δ-phase) for 3D/2D (C₆Br, IPA), likely due to the high polarity of IPA, or moisture dissolved in IPA, causing etching of the 3D perovskite surface layer by removing MA/FA halides and altering the chemical composition at the 3D/2D interface (FIG. 1D). This δ-phase is not detected on the 3D/2D (C₆Br, CF) perovskite. The δ-phase has been correlated to lower device performance and operational stability and should be avoided for optimal device performance. See, Turren-Cruz, S.-H. et al. Enhanced charge carrier mobility and lifetime suppress hysteresis and improve efficiency in planar perovskite solar cells. Energy Environ. Sci. 11, 78-86 (2018), which is incorporated by reference in its entirety.

Comparisons of device efficiency/stability demonstrate the impact of the SPD strategy described herein. FIG. 1E shows J-V curves of representative 3D/2D PSCs fabricated using IPA or CF. A 3D/2D (C₆Br, IPA) PSC shows an open-circuit voltage (V_{OC}) of 1.14 V and a PCE of 21.3%, which is comparable to previously reported defect-passivated PSCs. See, Cho, Y. et al. Mixed 3D-2D Passivation Treatment for Mixed-Cation Lead Mixed-Halide Perovskite Solar Cells for Higher Efficiency and Better Stability. Adv. Energy Mater. 1703392 (2018). doi:10.1002/aenm.201703392 and Cho, K. T. et al. Highly efficient perovskite solar cells with a compositionally engineered perovskite/hole transporting material interface. Energy Environ. Sci. 10, 621-627 (2017), each of which is incorporated by reference in its entirety. This strategy using CF further increases device performance, achieving a V_{OC} of 1.16 V and a PCE of over 22%. In addition, when the J-V scan is repeatedly performed under continuous light illumination, putting the PSCs under operational stress, the 3D/2D (C₆Br, CF) PSCs shows superior stability over the 3D/2D (C₆Br, IPA) PSCs (FIG. 1F). These results indicate that the SPD strategy using CF as a solvent maximizes the effect of the 2D perovskite treatment through defect passivation, leading to improved device performance.

The solubility and XRD results above support the use of CF instead of IPA during 2D perovskite treatment, leading to PSCs with higher performance and greater stability. Three different 2D perovskites can be incorporated with varying carbon chain lengths on 3D perovskite films: n-Butylammonium bromide (C₄Br), n-Hexylammonium bromide (C₆Br), and n-Octylammonium bromide (C₈Br). The alkyl chain length in 2D perovskite structures has been previously shown to affect defect passivation and thus device performance. See, Zheng, X. et al. Defect passivation in hybrid perovskite solar cells using quaternary ammonium halide anions and cations. Nat. Energy 2, 17102 (2017), Jung, M., Shin, T. J., Seo, J., Kim, G. & Seok, S. Il. Structural features and their functions in surfactant-armoured methylammonium lead iodide perovskites for highly efficient and stable solar cells. Energy Environ. Sci. (2018). doi:10.1039/C8EE00995C, and Zhao, T., Chueh, C. C., Chen, Q., Rajagopal, A. & Jen, A. K. Y. Defect Passivation of Organic-Inorganic Hybrid Perovskites by Diammonium Iodide toward High-Performance Photovoltaic Devices. ACS Energy Lett. 1, 757-763 (2016)each of which is incorporated by reference in its entirety.

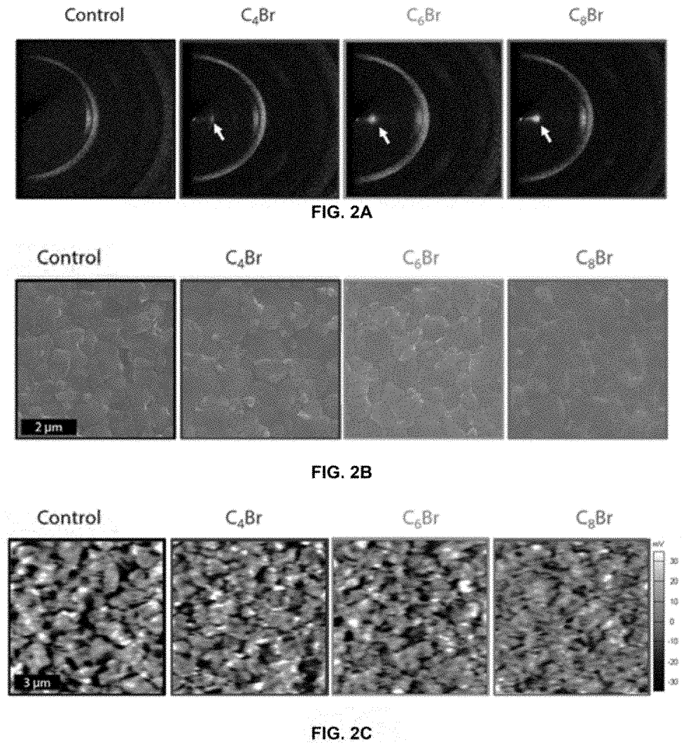

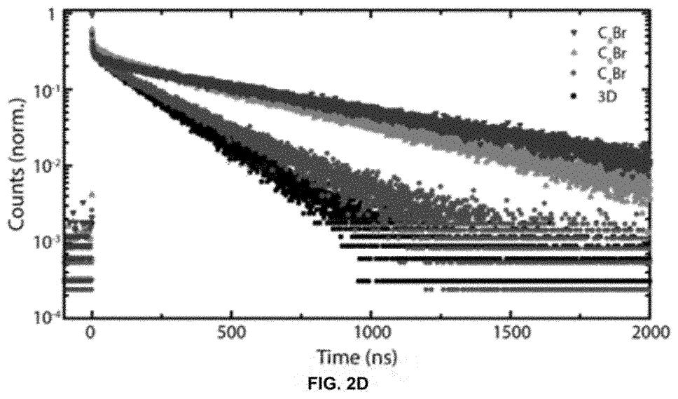

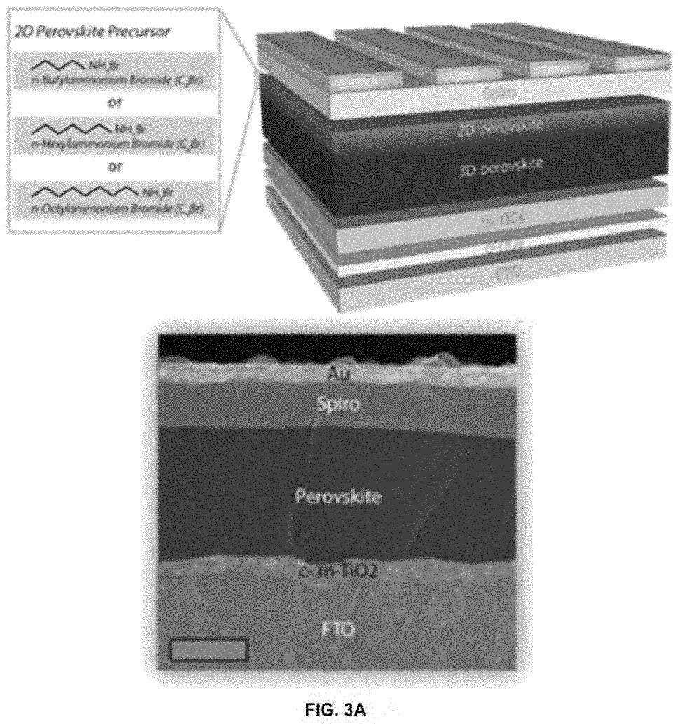

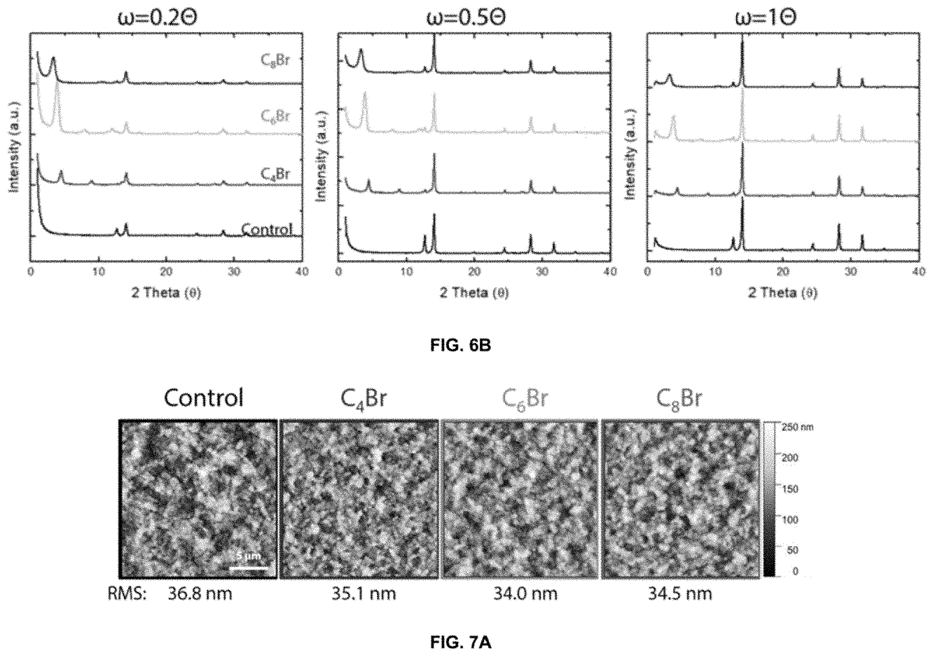

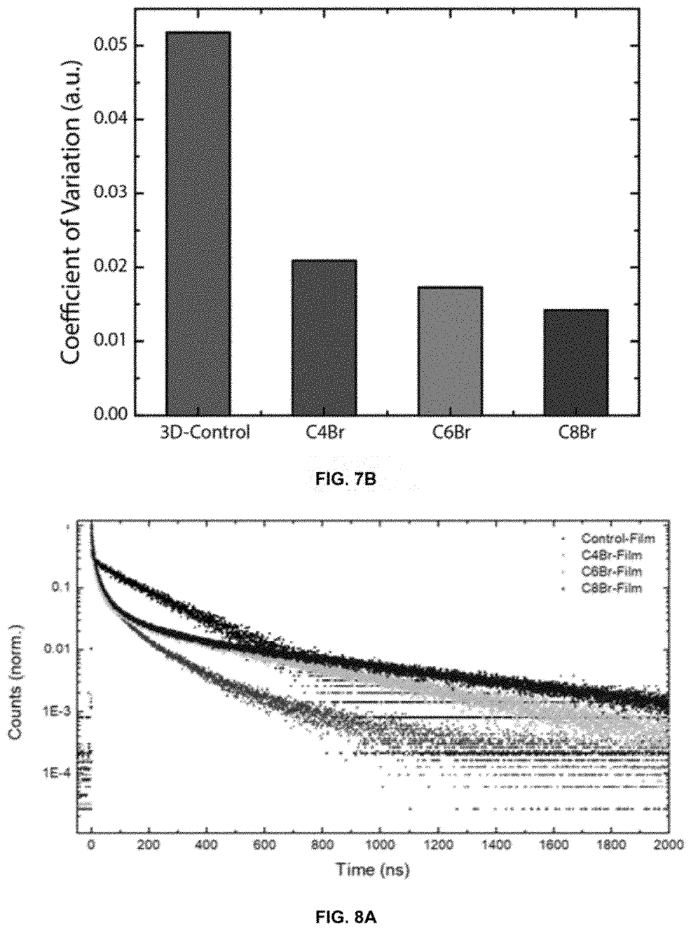

FIG. 2A shows the 2-dimentional XRD (XRD²) pattern of 3D and 3D/2D perovskites with varying alkyl chain lengths (C₄Br, C₆Br, and C₈Br). See, Tsai, H. et al. High-efficiency two-dimensional Ruddlesden-Popper perovskite solar cells. Nature 536, 312-316 (2016), which is incorporated by reference in its entirety. Upon 2D perovskite treatment, a peak appears at ˜4° (white arrow), shifting to lower angle with increasing chain length due to their larger organic spacing, as has been previously been observed (FIG. 6A). See, Gélvez-Rueda, M. C. et al. Interconversion between Free Charges and Bound Excitons in 2D Hybrid Lead Halide Perovskites. J. Phys. Chem. C 121, 26566-26574 (2017), which is incorporated by reference in its entirety. The single confined spot on the diffraction ring in the XRD² pattern for all three 2D perovskites indicates a planar (001) orientation relative to the underlying 3D structure. Although the 2D perovskite layer on the 3D perovskites is too thin for a quantitative determination of its thickness, grazing incident XRD (GIXRD) shows a decrease in the 2D perovskite peak and an increase in PbI₂ and 3D perovskite peaks at relatively low incident angles (0.2-1 Θ), indicating that the 2D perovskite is limited to the very surface of the film (FIG. 6B). The morphological changes on the perovskite surface is investigated using planar SEM. While all samples are pinhole-free with a high density of perovskite crystals, 3D/2D perovskites have noticeably less defined grain boundaries compared to the 3D control; increasing the alkyl chain length leads to less visible perovskite grain boundaries. This is consistent with a thin 2D perovskite layer on top of the 3D perovskite film and the filling of grain boundaries. A reduced surface roughness is also demonstrated using atomic force microscopy (AFM) (FIG. 7A).

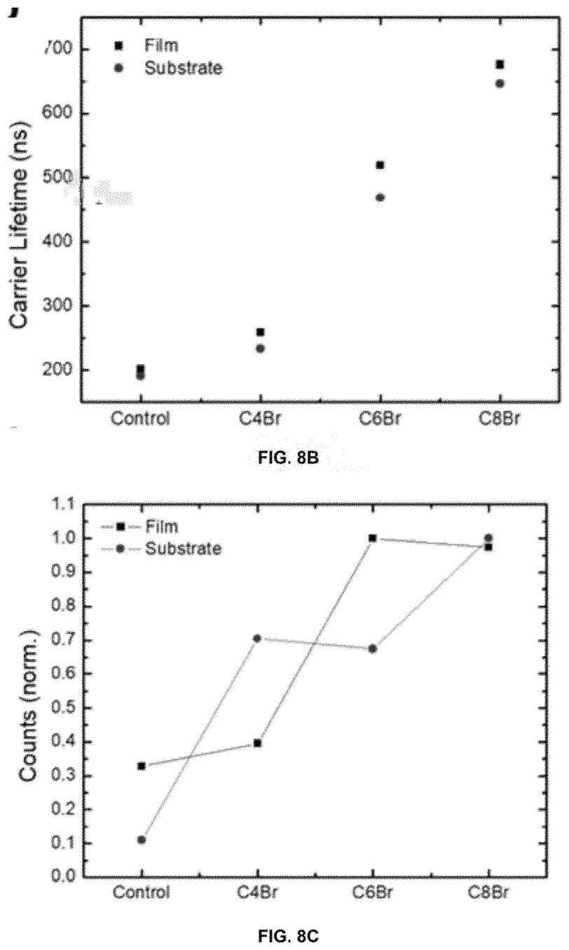

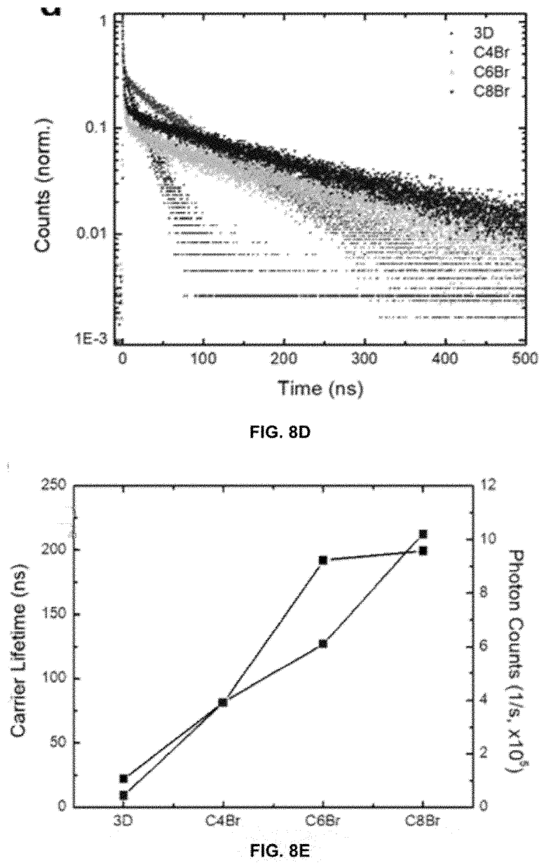

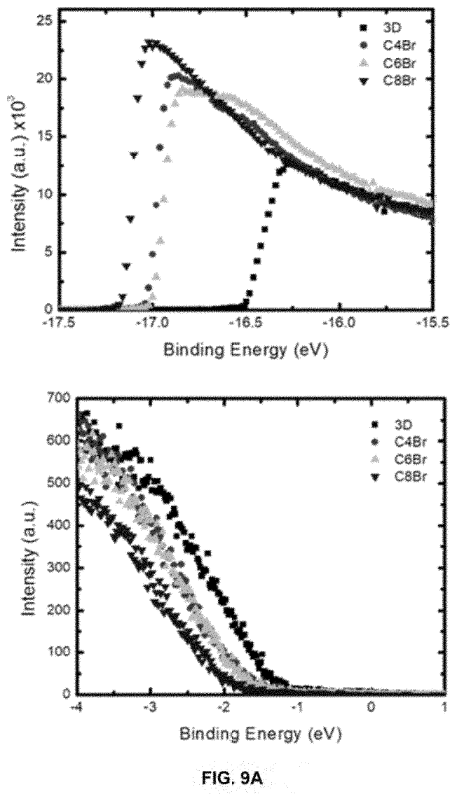

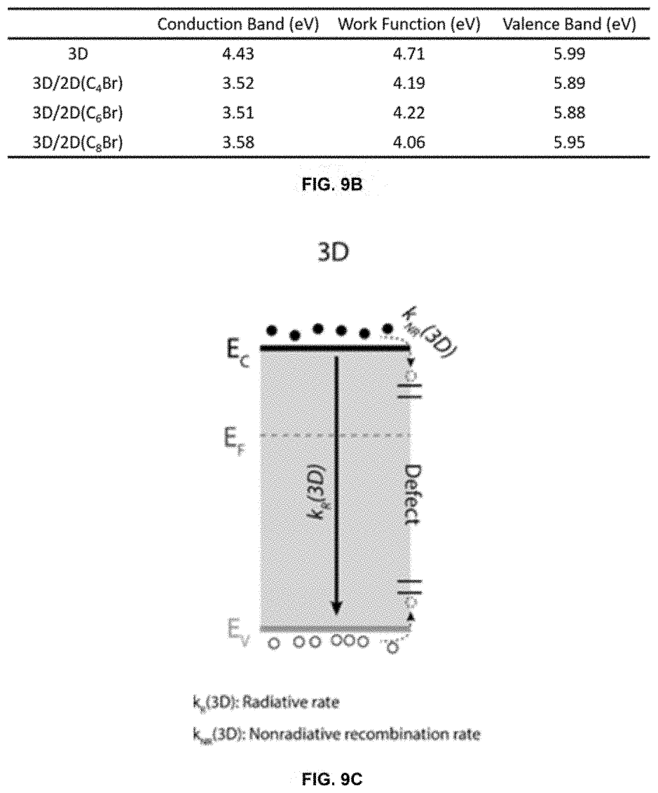

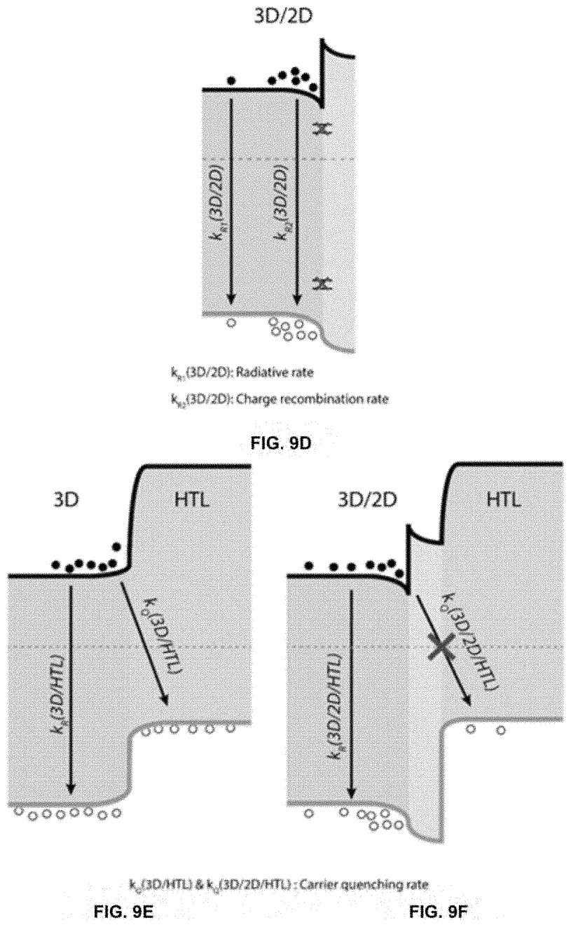

The effect of the 2D perovskite layer on the passivation of surface and grain boundary defects is investigated using Kelvin probe force microscopy (KPFM) by measuring the contact potential difference (CPD) between the AFM tip and the sample surface (FIG. 2C). See, Cho, Y. et al. Mixed 3D-2D Passivation Treatment for Mixed-Cation Lead Mixed-Halide Perovskite Solar Cells for Higher Efficiency and Better Stability. Adv. Energy Mater. 1703392 (2018). doi:10.1002/aenm.201703392, Lee, D. S. et al. Passivation of Grain Boundaries by Phenethylammonium in Formamidinium-Methylammonium Lead Halide Perovskite Solar Cells. ACS Energy Lett. 647-654 (2018). doi:10.1021/acsenergylett.8b00121, Ahn, N. et al. Trapped charge-driven degradation of perovskite solar cells. Nat. Commun. 7, 13422 (2016), and Ciro, J. et al. Optimization of the Ag/PCBM interface by a rhodamine interlayer to enhance the efficiency and stability of perovskite solar cells. Nanoscale 9, 9440-9446 (2017), each of which is incorporated by reference in its entirety. Remarkably, upon 2D perovskite treatment, the perovskite films show a significant flattening of the potential distribution suggesting that alkylammonium based 2D perovskite interlayers are effective at passivating surface/grain boundary traps (FIG. 7B). See, Cho, Y. et al. Mixed 3D-2D Passivation Treatment for Mixed-Cation Lead Mixed-Halide Perovskite Solar Cells for Higher Efficiency and Better Stability. Adv. Energy Mater. 1703392 (2018). doi:10.1002/aenm.201703392, Ciro, J. et al. Optimization of the Ag/PCBM interface by a rhodamine interlayer to enhance the efficiency and stability of perovskite solar cells. Nanoscale 9, 9440-9446 (2017), and Chen, P. et al. In Situ Growth of 2D Perovskite Capping Layer for Stable and Efficient Perovskite Solar Cells. Adv. Funct. Mater. 1706923 (2018). doi:10.1002/adfm.201706923, each of which is incorporated by reference in its entirety. Additionally, time-resolved photoluminescence (TRPL) is used to measure carrier lifetimes for 3D control and 3D/2D perovskites (FIG. 2D). All three 3D/2D perovskite samples show an increase in carrier lifetime compared to the 3D control. UPS and TRPL measurements indicate that the wide band gap 2D perovskite prevents carrier quenching (FIGS. 8A-8E and 9A-9F). 2D perovskite treatment is effective in passivating surface/grain boundaries, reducing non-radiative recombination pathways and resulting in improved device performance.

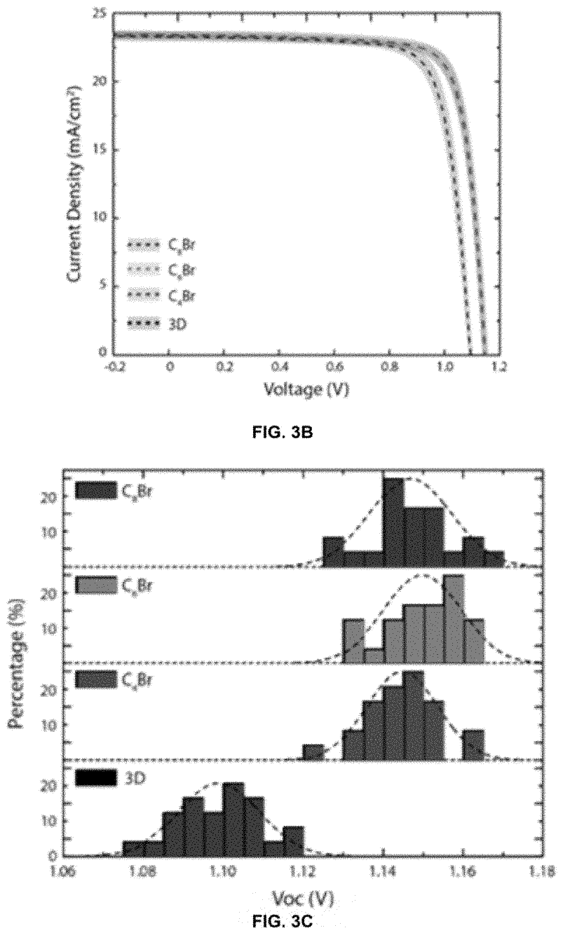

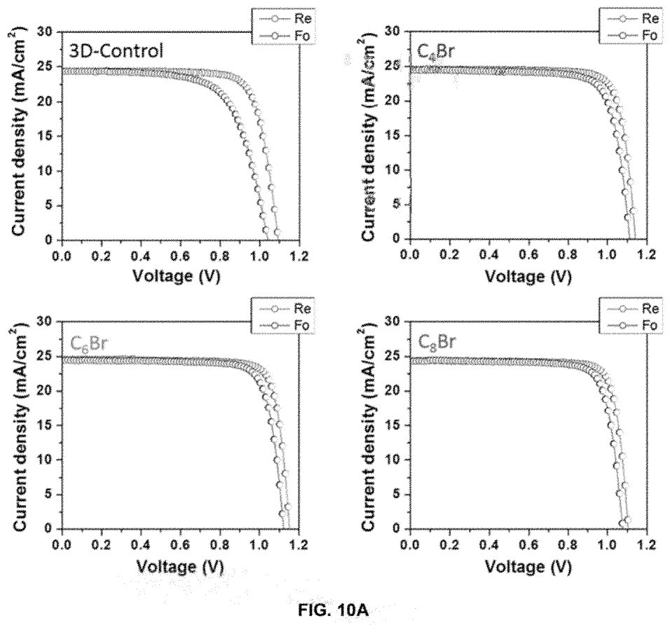

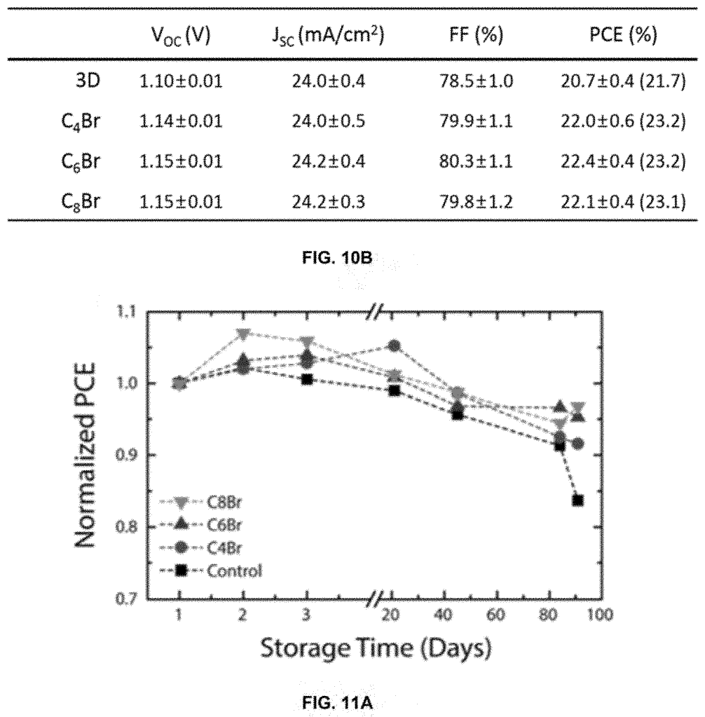

PSCs were fabricated without (3D control) and with various 2D perovskite precursors (C₄Br, C₆Br and C₈Br) to verify that the improved optoelectronic properties above translate to better performing devices. FIG. 3A shows a schematic illustration of the 3D/2D PSC along with a false colored cross-sectional SEM image. FIG. 3B shows the average J-V curves of the fabricated 3D control and 3D/2D PSCs. The average PCEs for 3D/2D devices are noticeably higher than the control (˜22% vs ˜20%) with reduced hysteresis in the J-V curves regardless of their alkyl chain length (FIGS. 10A-10B). The improved PCE can be mainly ascribed to an increase in the V_{OC} of ˜50 mV with 2D perovskite treatment. FIG. 3C displays the V_{OC} distribution of the corresponding devices. The average V_{OC} is 1.10, 1.14, 1.15 and 1.15 V for the 3D control, C₄Br, C₆Br, and C₈Br-treated devices, respectively, and the champion V_{OC} (1.17 V) is achieved in a C₈Br-treated device. The increase in V_{OC} is due to increased carrier lifetime. This result indicates that longer-chained 2D perovskite can effectively passivate surface and grain boundaries. See, Shao, Y., Xiao, Z., Bi, C., Yuan, Y. & Huang, J. Origin and elimination of photocurrent hysteresis by fullerene passivation in CH₃NH₃PbI₃ planar heterojunction solar cells. Nat. Commun. 5, 5784 (2014), and Son, D.-Y. et al. Universal Approach toward Hysteresis-Free Perovskite Solar Cell via Defect Engineering. J. Am. Chem. Soc. 140, 1358-1364 (2018), each of which is incorporated by reference in its entirety. Although a slight difference in photovoltaic properties between 2D treated devices is observed, their device performance differences are not statistically significant with the best PCEs reaching ˜23% for all alkyl chain lengths. Most studies to date have focused on the chemical nature of 2D perovskite materials to fabricate high performance 3D/2D PSCs. The finding here, however, suggests that the dominant factor in the fabrication of 3D/2D PSCs is how the in-situ synthesis of 2D perovskite is performed, rather than the exact composition of the 2D layer as device performance seems insensitive to the type of 2D perovskite.

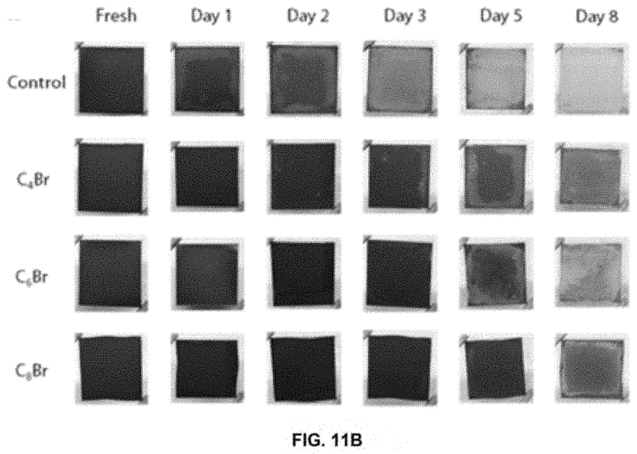

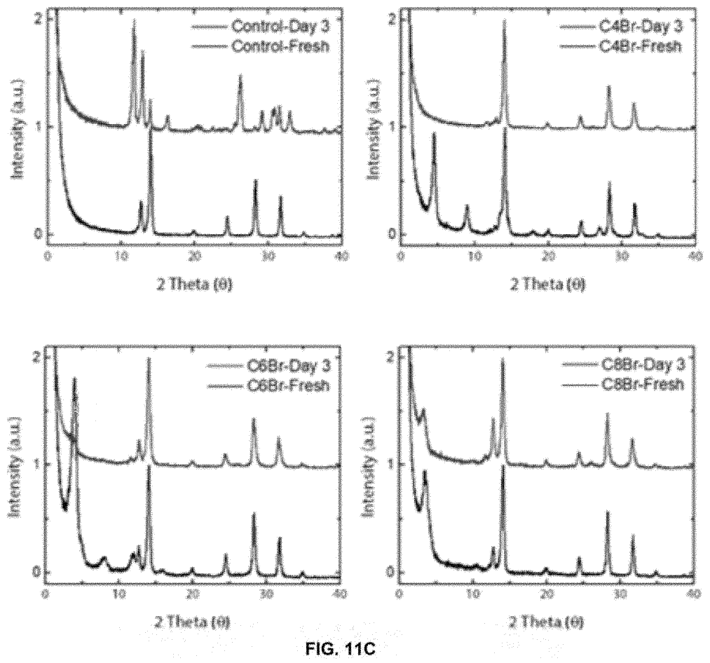

3D and 3D/2D PSCs retained most of their initial device performance when stored in dark and dry conditions, ˜20% relative humidity (RH), (FIG. 11A). FIG. 11B shows a series of photographs of perovskite substrates stored in a humidity chamber (˜90% RH) at room temperature. The 3D control showed immediate bleaching of the perovskite after day 1 and turned almost colorless after day 8. For the 2D perovskite treated substrates, all three samples showed superior stability compared to the 3D control, and increasing the alkyl chain length yielded superior resistance to humidity suggesting that the longer-chain 2D perovskites are advantageous for the scale up of PSCs.

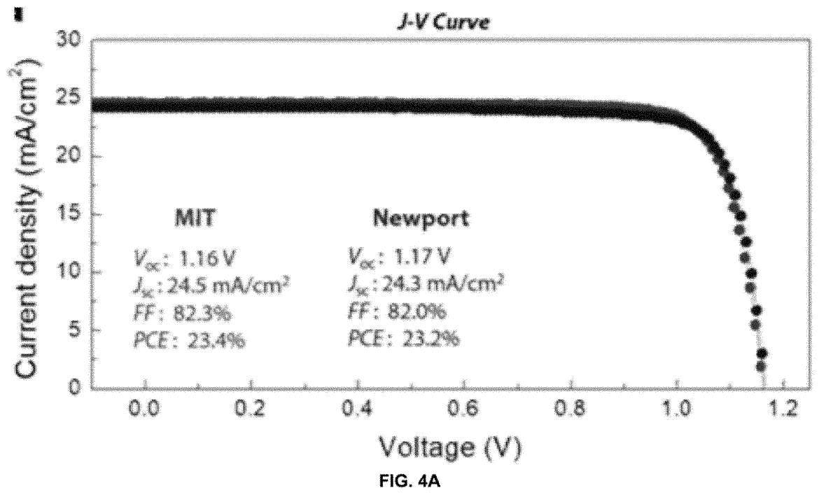

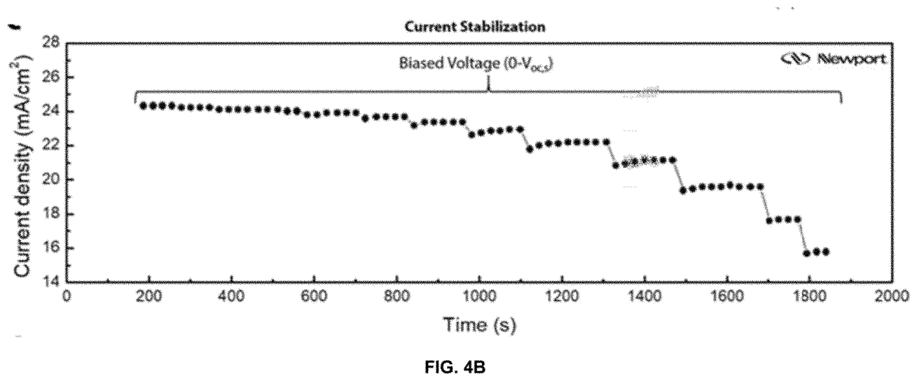

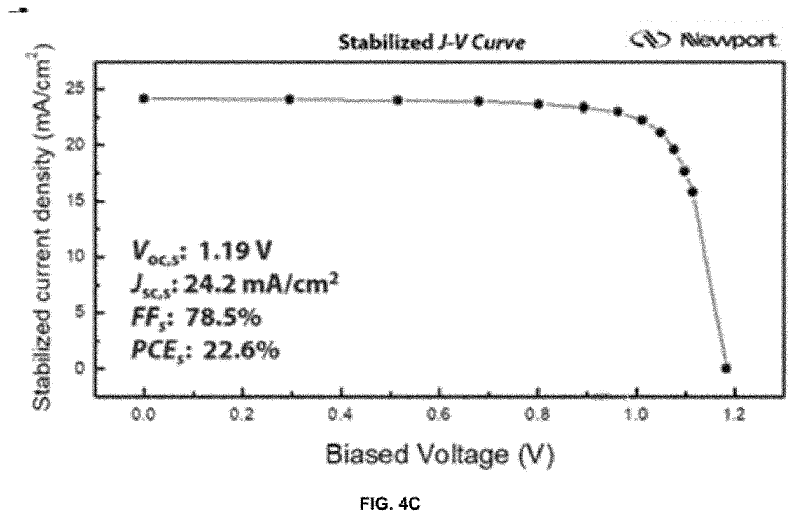

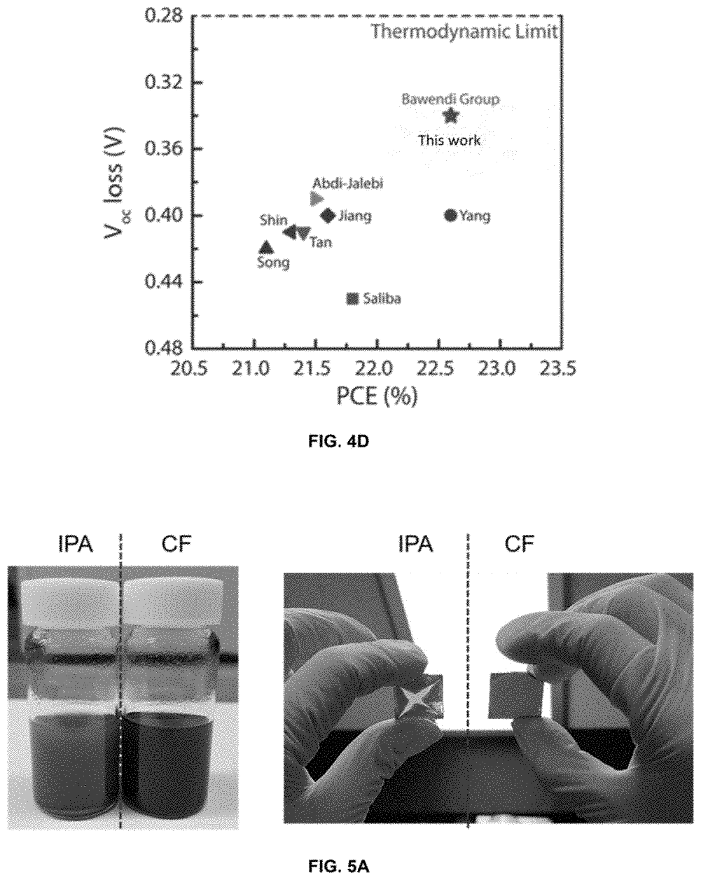

Through optimization of device performance and with an anti-reflective coating, a reverse J-V PCE of 23.4% (FIG. 4A) was achieved. To ensure reliability of the data, 3D/2D PSCs were sent for certification to the Newport Corporation Technology and Application Center

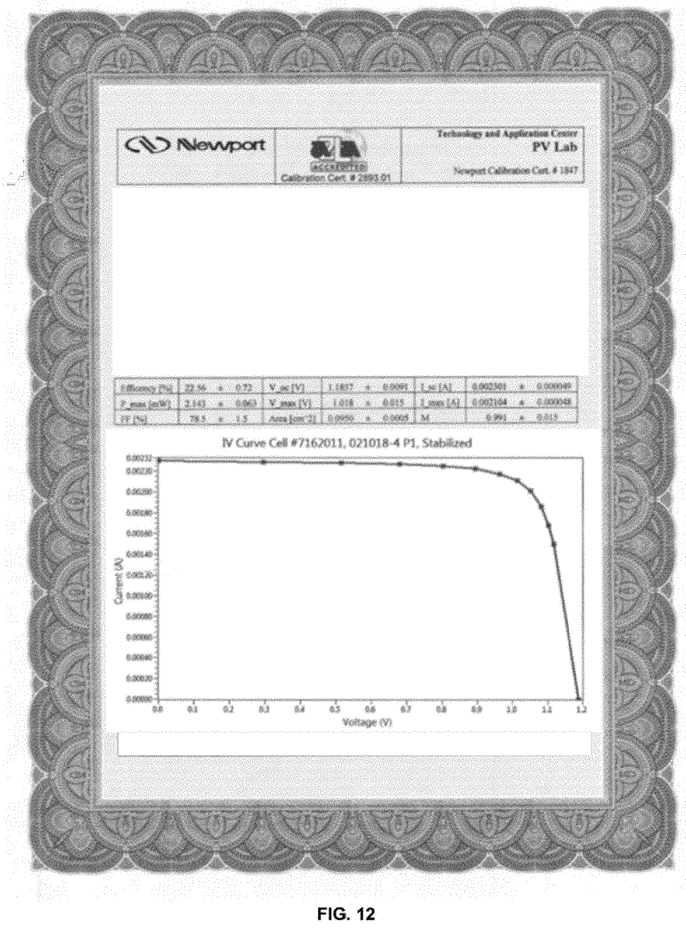

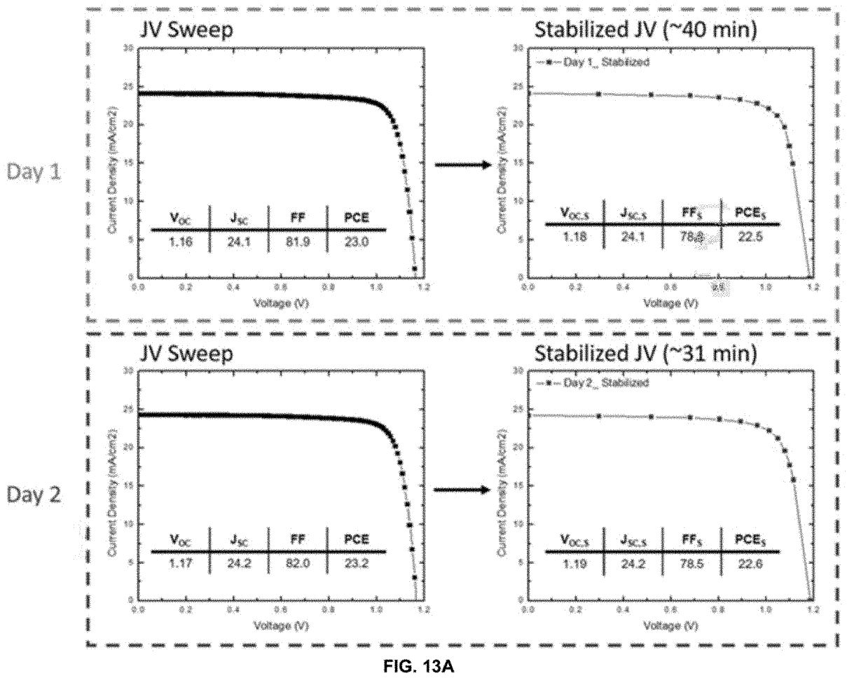

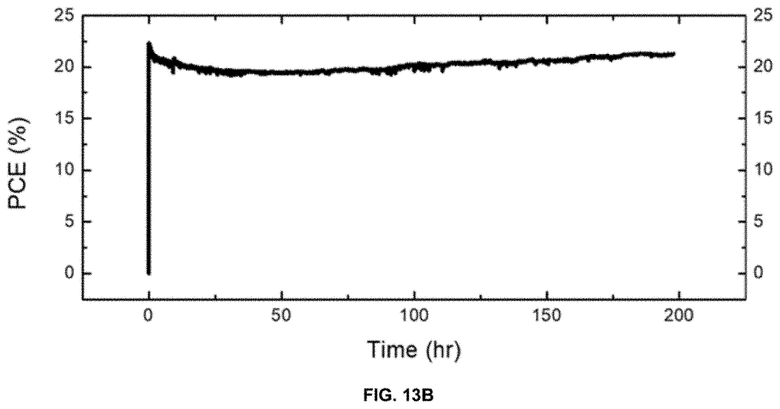

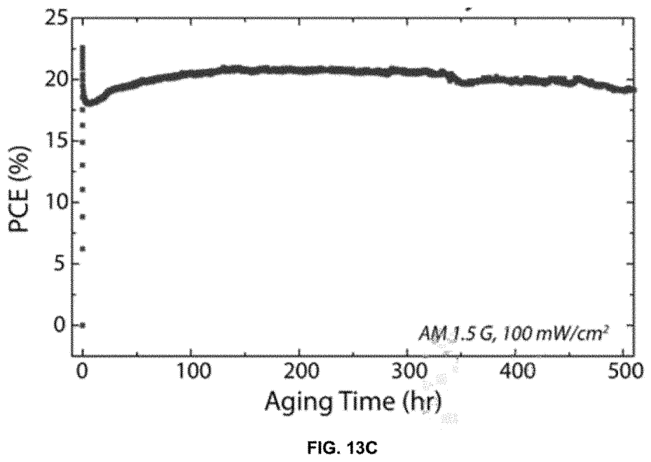

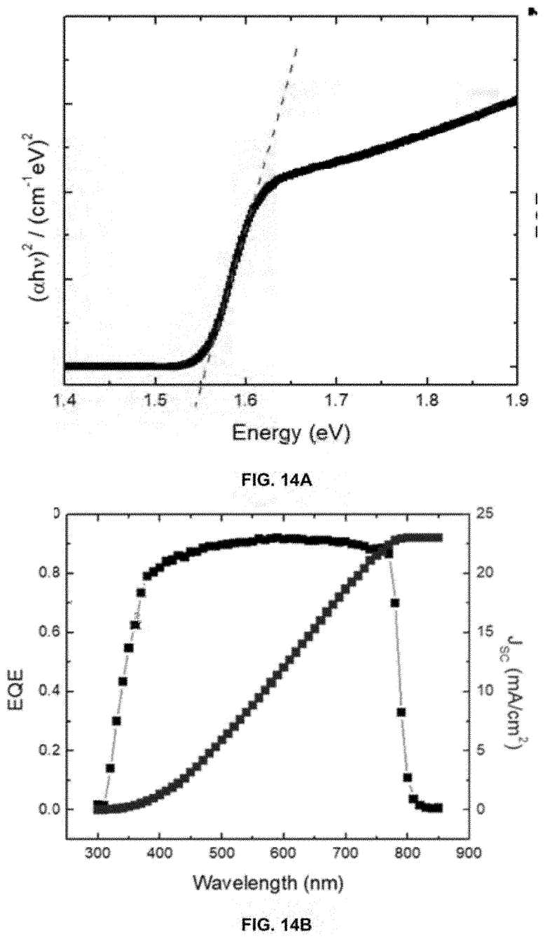

Photovoltaic Lab (Newport), an accredited testing laboratory, confirming a reverse J-V PCE of 23.2%. Quantifying PCEs for perovskite solar cells from J-V scans is problematic because conventional J-V sweeps can give rise to out-of-equilibrium effects associated with the dynamic ionic characteristics of the perovskite layer. See, Tress, W. Metal Halide Perovskites as Mixed Electronic-Ionic Conductors: Challenges and Opportunities—From Hysteresis to Memristivity. J. Phys. Chem. Lett. 8, 3106-3114 (2017), which is incorporated by reference in its entirety. In addition, several groups have noted that J-V sweeps do not reflect the true efficiency of a PSC device, and that even the absence of hysteresis in J-V measurements of PSCs is insufficient to predict steady-state device characteristics, leading to an overestimation of steady-state device performance. See, Dunbar, R. B. et al. How reliable are efficiency measurements of perovskite solar cells? The first inter-comparison, between two accredited and eight non-accredited laboratories. J. Mater. Chem. A 5, 22542-22558 (2017), Zimmermann, E. et al. Characterization of perovskite solar cells: Towards a reliable measurement protocol. APL Mater. 4, 091901 (2016), and Wagner, L., Chacko, S., Mathiazhagan, G., Mastroianni, S. & Hinsch, A. High Photovoltage of 1 V on a Steady-State Certified Hole Transport Layer-Free Perovskite Solar Cell by a Molten-Salt Approach. ACS Energy Lett. 1122-1127 (2018). doi:10.1021/acsenergylett.8b00293, each of which is incorporated by reference in its entirety. PSCs require light soaking for some period of time before reaching a stable state, and defective PSCs do not maintain their maximum efficiency under illumination. See, Saliba, M. Perovskite solar cells must come of age. Science 359, 388-389 (2018), which is incorporated by reference in its entirety. As a result, the most accurate way to translate device performance to that expected in an operational solar cell is to perform the measurement under stabilized conditions. Stabilized measurements were performed to better quantify the PCE (FIG. 12). The V_{OC} and current density were first measured by holding the bias current (or voltage) until the measured voltage (or current density) remains unchanged at the 0.03% level. FIG. 4B shows the measurement determining the stabilized V_{OC} (V_{OC,S}) where the initial V_{OC} increases from ˜1.16V, stabilizing at ˜1.19V. The same principle is applied for the stabilized current density, but with the bias voltage held and the current density monitored at each voltage (FIG. 4C). A total of 13 voltage points were measured (from 0 to V_{OC,S}) with a total measurement time of ˜31 min. FIG. 4D shows the J-V curve extracted from the asymptotic measurement with V_{OC,S}: 1.19 V, J_{SC,S}: 24.2 mA/cm², FFs: 78.5%, and PCEs: 22.6% (subscript S means stabilized). This is the highest certified stabilized PCE thus far for PSCs and the first demonstration of a certified stabilized efficiency over 20%. To confirm the reliability of the certification result, the same pad was tested over the course of two days (FIG. 13A), resulting in an almost identical result for both measurements, further supporting the enhanced operational stability of the PSCs and the importance of the SPD strategy. In addition, the long term stability of the PSC was tested with maximum power point (MPP) tracking under full solar illumination without an ultra-violet cut-off filter (UV-filter). The 3D/2D PSC, with an initial PCE of 22.3%, maintained >20% PCE over 200 hrs (FIGS. 13B-13C), even without incorporation of Cs and Rb as additives. FIG. 4E summarizes the V_{OC} loss and the device efficiency of recently reported high efficiency PSCs. The 3D/2D PSCs result in the lowest V_{OC} loss (FIGS. 14A-14B) and the highest PCE reported to date, regardless of device structure and perovskite composition. See, Polman, A., Knight, M., Garnett, E. C., Ehrler, B. & Sinke, W. C. Photovoltaic materials: Present efficiencies and future challenges. Science 352, aad4424 (2016), which is incorporated by reference in its entirety. The SPD strategy enables realization of optimal 3D/2D perovskite interfaces for efficient device performance and open a potential path to environmentally-stable, and operationally-efficient low-cost solar cells.

A SPD strategy durinng 3D/2D heterostructure PSC fabrication effectively passivates interface defects, minimizes carrier quenching, and results in a record stabilized device efficiency. In addition to effectively passivating interface defects, the 2D treatment that described herein is scalable. Various printing methods that could be used for the scaled-up production of heterojunction PSCs (ink-jet printing, roll-to-roll printing, and blade coating) inevitability employ long contact time between the underlying perovskite layer and the solvent used for surface treatment. As a result, the newly developed SPD strategy provides an ideal platform for the scaled-up production of heterojunction PSCs since it is insensitive to solvent contact time.

FIGS. 1A-1F represent investigation of the effect of the SPD strategy on 3D/2D perovskite fabrication. FIG. 1A shows a qualitative solubility chart for solvents commonly used in PSC fabrication. Chloroform has the ideal polarity to selectively dissolve only the 2D perovskite precursors. FIG. 1B shows solubility of C₆Br and FAI in CF and IPA illustrating the appropriateness of using CF for the 2D perovskite treatment. FIG. 1C shows grazing incidence XRD of 3D and 3D/2D perovskites fabricated using CF or IPA, and XRD of pristine 2D perovskite with different compositions. FIG. 1D shows XRD of the 3D/2D (CF) and 3D/2D (IPA) perovskites showing the formation of the δ-phase)(-11.5° in 3D/2D (IPA) perovskites. FIG. 1E shows J-V curve of 3D/2D (CF) and 3D/2D (IPA) PSCs. FIG. 1F shows light stability test of 3D/2D (CF) and 3D/2D (IPA) PSCs showing higher device performance and stability for 3D/2D (CF) PSCs.

FIGS. 2A-2D represent characterization of 3D control and 3D/2D perovskites. FIGS. 2A shows XRD image of 3D control and three different 3D/2D (C₄Br, C₆Br, C₈Br) perovskites. White arrows indicate the (001) peak of the 2D perovskite. FIG. 2B shows planar SEM of 3D control and 3D/2D perovskite samples. FIG. 2C shows KPFM images of 3D control and 3D/2D perovskite samples. SEM images show that the grain boundary is less distinct for the 3D/2D perovskite and the same behavior is observed in potential mapping from KPFM. FIG. 2D shows a TRPL trace of 3D and 3D/2D perovskite films deposited on a quartz substrate. The sample was excited through the quartz substrate. An increase in the carrier lifetime is observed with 2D perovskite treatment.

FIGS. 3A-3C show PSC device characterization. FIG. 3A shows a schematic illustration of a 3D/2D PSC with false colored cross-sectional SEM (scale bar: 500 nm). FIG. 3B shows J-V curves of 3D and 3D/2D (C₄Br, C₆Br, CgBr) PSCs, with average and standard deviation shown as a dashed line and shaded area, respectively. FIG. 3C shows a histogram of V_{OC} for 3D and 3D/2D (C₄Br, C₆Br, CgBr) PSCs.

FIGS. 4A-4d show stabilization measurements of 3D/2D PSCs. FIG. 4A shows 3D/2D PSC devices with champion efficiency measured at MIT and at Newport. FIG. 4B shows asymptotical measurement on stabilized open-circuit-voltage (V_{OC,S}). FIG. 4C shows stabilization of current density. FIG. 4D shows stabilized J-V curve extracted from FIG. 4A and FIG. 4C with stabilized power conversion efficiency (PCEs) of 22.6%. FIG. 4E shows V_{OC} loss and PCE of recently reported high performance PSC. The Shockley-Queisser (S-Q) V_{OC} loss limit of ˜0.28 V is shown as the red dotted line.

Methods

Chemicals

Fluorine-doped tin oxide (FTO) were purchased from Pilkington (TEC8). Titanium diisopropoxide bis(acetylacetonate) solution (75 wt. % in isopropanol), DMF, DMSO, diethyl ether, chlorobenzene, chloroform, isopropyl alcohol, Lithium Bis(trifluoromethanesulfonyl)imide salt (Li-TFSI), and 4-tert-butylpyridine (tBP) were purchased from Sigma-Aldrich. TiO₂ paste (SC-HT040) was purchased from ShareChem. 2,2′,7,7′-Tetrakis(N,N-di-p-methoxyphenylamino)-9,9′-spirobifluorene (Spiro-OMeTAD, LT-S922) and Tris(2-(1H-pyrazol-1-yl)-4-tert-butylpyridine)-cobalt(III)Tris(bis(trifluoromethylsulfonyl)imide)) salt (Co(III) TFSI) were purchased from Lumtec. Methylammonium chloride (MAC1) was purchased from Dyenamo. Formamidinium (FA) iodide (FAI), methylammonium bromide (MABr), n-butylammonium bromide (C₄Br), n-hexylammonium bromide (C₆Br), and n-octylammonium bromide (C₈Br) were purchased from GreatCell Solar. Lead iodide (PbI₂) and lead bromide (PbBr₂) were purchased from TCI America. Au pellets were purchased from Kurt J. Lesker.

Device Fabrication

FTO substrates were cleaned by sonicating in deionized water, acetone, and isopropyl alcohol for 10 min each. A blocking TiO₂ layer was deposited via spray pyrolysis using a 20 mM titanium diisopropoxide bis(acetylacetonate) solution at 450° C. A mesoporous TiO₂ layer was deposited by spin coating a TiO₂ paste and was sintered at 500 ° C. for 2 hrs. A Li-TFSI solution (45 mg/mL in acetonitrile) was spin coated onto the TiO₂ layer and heat treated at 500° C. for 2 hrs. The FTO/TiO₂ substrate was plasma treated to make the surface hydrophilic before pumping it into a nitrogen glovebox. The (FAPbI₃)_{0.92}(MAPbBr₃)_{0.08} perovskite solution (1.53 M PbI₂, 1.4 M FAI, 0.11 M MAPbBr₃, 0.5 M MAC1 in DMF:DMSO=8:1 volume ratio) was spin coated at 1000 rpm for 10 sec and 5000 rpm for 30 sec onto the FTO/TiO₂ substrate. 10 seconds into the 5000 rpm setting, 600 μL of diethyl ether was deposited and the FTO/TiO₂/perovskite sample was heat treated at 150° C. for 10 min. For in-situ 2D perovskite synthesis, a solution of 2D perovskite precursors (10 mM in chloroform or IPA) was deposited and spin coated at 5000 rpm for 30 sec on the FTO/TiO₂/perovskite sample, followed by heat treatment at 100° C. for 5 min. The hole transporting layer was deposited by spin coating a solution consisting of 50 mg of Spiro-OMeTAD, 19.5 μL of tBP, 5 μL of Co(III) TFSI solution (0.25 M in acetonitrile), 11.5 of Li-TFSI solution (1.8 M in acetonitrile), and 547 μL of chlorobenzene at 4000 rpm for 20 sec onto the sample. The Au electrode (100 nm) was deposited by thermal evaporation.

Device Characterization

Current density-voltage (J-V) curves were recorded using a solar simulator (Newport, Oriel Class A, 91195A) and a source meter (Keithley 2420). The illumination was set to AM 1.5 G and calibrated to 100 mW/cm² using a calibrated silicon reference cell. The step voltage is 10 mV and the delay time is 50 ms. The active area was controlled by using a dark mask with an aperture of 0.095 cm² (measured at Newport). For the stability measurement, the devices were encapsulated and tested under AM 1.5 G and 100 mW/cm² in an ambient condition. The MPP was measured via perturb and observe algorithm implemented onto a custom LabView code.

Scanning Electron Microscope (SEM) and X-Ray Diffraction (XRD)

The SEM images were recorded using a Zeiss Merlin High-resolution SEM and the XRD patterns were collected using a Rigaku SmartLab and a Bruker D8 Discovery Diffractometer with a General Area Detector Diffraction System.

AFM and KPFM

AFM measurements were performed with a Cypher S (Asylum Research). Topography images were collected using an uncoated silicon tip at a resonant frequency of 300 kHz and a spring constant of 26 N/m in tapping mode. All images are shown with line-wise flattening to remove tilting effects of the substrate plane. Root mean square (RMS) values were determined by 20×20 μm² images. Kelvin probe force measurements were performed with a MFP-3D AFM (Asylum Research) in air. PtIr and Ti/Ir electrilevers were employed at a lift height of 25 nm and with a 3 V AC bias applied to the tip to induce an electrostatic force between the tip and sample. The surface potential difference between the tip and sample is regarded as the DC bias applied to the tip in order to null the tip oscillations.

Ultraviolet Photoelectron Spectroscopy (UPS)

UPS was conducted in an Omicron ultrahigh vacuum (UHV) system with base pressure of approximately 1 e-10 mbar. Perovskite films prepared on un-patterned ITO-coated glass were grounded to steel UPS sample plates via carbon tape and subsequently loaded from air into the UHV system. Measurements were carried out at a pressure of approximately 1 e-7 mbar and sample bias of −5.0V, under excitation from the He I line (21.22 eV) of a helium discharge lamp. Spectra were collected using a constant analyzer energy of 5 eV, step size of 20 meV, and step delay of 20 ms and were calibrated to the Fermi edge of a thermally-evaporated Au sample. Cutoff energies were found by intersecting a linear fit of each cutoff region with a linear extrapolation of the corresponding baseline.

Time Resolved Photoluminescence (TRPL)

Photoluminescence lifetimes were collected using a 532 nm picosecond pulsed diode laser (Picoquant; LDH-P-FA-266) adjusted to a repetition rate of 200 kHz using a pulse generator (Stanford Research; DG535). The laser was set to an average power of 0.2 μW using neutral density filters and focused to a 150 μm spot on the perovskite film. The emission from the film was collected and collimated using an off-axis parabolic mirror (Thorlabs; MPD269V) and measured with a silicon single-photon avalanche diode (SPAD) detector (Micro Photon Devices; $PD-100-C0C). Scattered laser excitation was suppressed using a 532 nm notch filter (Chroma; ZET532NF) and a 550 nm longpass filter (Thorlabs; FELH0550). The 532 nm laser harmonic was suppressed using a 900 nm shortpass filter (Thorlabs; FESH0900). Photon arrival times were recorded using a time-correlated single photon counting card (Picoquant; PicoHarp 300) and all analysis was performed in Matlab.

FIGS. 5A-5B show the effect of IPA and CF on 3D perovskite and on the formation of 3D/2D perovskites. FIG. 5A shows photographs of vials of FAPbI₃ perovskite powder (left) dispersed in isopropyl alcohol (IPA) or chloroform (CF) left overnight, and thin films of (FAPbI₃)_{0.92}(MAPbBr₃)_{0.08} perovskite (right) after being submerged in isopropyl alcohol (IPA) or chloroform (CF) overnight in closed vials at room temperature and in air. The yellow color observed in the IPA solution (left vial in a) indicates dissolution of perovskite. The yellow color observed in the IPA film (left substrate in a) also indicates dissolution of perovskite. FIG. 5B shows Planar SEM images of 3D, 3D/2D (IPA), and 3D/2D (CF) perovskites where C₆Br was used for the 2D perovskite. The grain boundary is most distinct for the 3D perovskite and least distinct for 3D/2D (CF) perovskite.

FIGS. 6A-6B show XRD and GIXRD pattern for the 3D control and three different 3D/2D perovskite samples. FIG. 6A shows the XRD shows the main 2D perovskite peak shifting to lower angles with increasing alkyl chain length. FIG. 6B shows GIXRD pattern at various incident angle (ω) on the 3D perovskite and 3D/2D perovskites with different alkyl chain length.

FIGS. 7A-7B show AFM and KPFM result on 3D and 3D/2D perovskite substrates. FIG. 7A shows AFM images of 3D (Control) and 3D/2D (C₄Br, C₆Br, C₈Br) perovskites and their surface roughness shown in RMS value. Surface roughness decreases upon 2D perovskite treatment. FIG. 7B shows coefficient of variation, defined as the standard deviation of the CPD intensity normalized to the average CPD intensity, calculated from KPFM images in FIG. 2C.

FIGS. 8A-8E show lifetime measurement on 3D and 3D/2D perovskites. FIG. 8A shows TRPL traces of 3D and 3D/2D perovskites on quartz substrates. “Film” indicates that the sample is excited from the perovskite film side. FIG. 8B shows carrier lifetimes extracted by fitting the long component of the lifetime traces (a above as well as from FIG. 2D). “Substrate” indicates that the sample is excited through the quartz substrate (in FIG. 2D). FIG. 8C shows normalized integrated photon counts from the TRPL measurements. FIG. 8D shows TRPL of 3D and 3D/2D perovskite samples with Spiro-OMeTAD as the hole transport layer, excited from the perovskite film side. FIG. 8E shows extracted carrier lifetimes and integrated photon counts (from FIG. 8D).

FIGS. 9A-9F show UPS measurement results and schematic illustration of band alignments for 3D and 3D/2D perovskite samples. FIG. 9A shows UPS spectra of 3D and three different 3D/2D perovskite substrates. FIG. 9B shows summary of energy levels determined from UPS measurements. Bandgaps of 1.53 eV and 2.37 eV were used to determine the conduction band of 3D and 3D/2D perovskites, respectively. FIGS. 9C-9F show energy band diagrams of various perovskite layers determined from UPS and TRPL measurements. CB, WF, and VB correspond to conduction band, work function, and valence band, respectively. Energy band diagram of 3D control (c) and 3D/2D perovskite (FIG. 9D), showing the passivation of surface defects with 2D perovskite treatment. Energy band diagram of 3D control (FIG. 9E) and 3D/2D perovskite (FIG. 9F) with the addition of the hole transport layer (HTL).

The band diagrams depicted in FIGS. 9C-9F provide an explanation of the observed kinetics in the TRPL traces and the observed increased device performance.

The 3D-control structure (FIG. 9C) depicts the band diagram and the observed recombination pathways based on TRPL measurements. The observed radiative rate, k_{R}(3D), is faster than the known intrinsic carrier lifetime in 3D perovskite thin films, likely due to the presence of non-radiative recombination pathways, k_{NR}(3D), associated with the surface. When a 2D layer is deposited on the 3D perovskite (FIG. 9D), TRPL measurements observed with excitation from the 3D perovskite side show an increase in carrier lifetimes, k_{R1}(3D/2D), compared to the 3D control perovskite. On the other hand, the lifetime trace shows a relatively fast component, k_{R2}(3D/2D), when the 3D/2D perovskite is excited from the 2D perovskite side, in addition to the long component (FIG. 8A). This behavior of different lifetime profiles depending on the excitation side is not observed in the 3D control perovskite where the lifetime traces are almost identical for both film and substrate excitation. The 2D perovskite interlayer was identified as a passivating layer that minimizes surface/interface trap states that otherwise would serve as non-radiative recombination centers. The additional passivation results in an increase in carrier lifetimes and the increase in detected photons. Furthermore, the fast radiative component, k_{R2}(3D/2D), can be due to a carrier buildup at the 3D/2D perovskite interface from band bending, which is supported by the UPS results. This carrier accumulation can contribute to the increase of V_{OC} of 3D/2D PSCs, in addition to the increase in the built-in potential due to the higher work function of 3D/2D perovskite.

The role of 2D perovskites on the 3D/2D perovskite structure can be further supported by TRPL measurement with the addition of hole transport layers (HTL), specifically Spiro-OMeTAD. FIGS. 9E-9F shows the band diagram of 3D/HTL and the 3D/2D/HTL structure and FIGS. 8D-8E shows the corresponding lifetime traces, carrier lifetime, and photon counts. The 3D/HTL structure shows significantly faster lifetime traces when compared to pristine 3D perovskites, due to quenching of one of the carrier (hole) into the HTL. On the other hand, a longer lifetime is observed for the 3D/2D/HTL structure compared to 3D/HTL. The limited quenching effect can be explained by the reduced recombination between the electron in the perovskite layer and the hole in the HTL due to the spatial separation and the energy barrier provided by the wide bandgap 2D perovskite.

In total, the 2D perovskite interlayer passivates the 3D perovskite surface traps and minimizes nonradiative recombination pathways, while providing a spatial separation and an energy barrier to minimize carrier quenching associated with the 3D perovskite/HTL interface. In eliminating intra-band gap states and removing nonradiative recombination pathways, the 2D perovskite interlayer provides an ideal interface for low V_{OC} loss and improved PCE.

FIGS. 10A-10B show hysteresis and summary of 3D and 3D/2D PSC device performance. FIG. 10A shows J-V curves of 3D and 3D/2D representative PSCs showing reduced hysteresis for 2D perovskite treated PSCs. “Re” is the reverse scan the “Fo” is the forward scan. FIG. 10B shows PCE average and standard deviation for 3D and 3D/2D PSCs measured over 20 devices. The PCE values in parentheses represent the result for the best-performing cells.

FIGS. 11A-11C show device stability and humidity resistance of 3D and 3D/2D PSCs and perovskite films. FIG. 11A shows normalized PCE as a function of storage time for 3D and 3D/2D PSCs. The devices were stored in dark and dry conditions between measurements. FIG. 11B shows photographs of 3D and 3D/2D perovskite films on glass substrates stored in a humidity chamber (˜90% RH) at room temperature as a function of storage time. The bleaching indicates decomposition of the 3D perovskite. The 3D/2D perovskite films showed higher resistance to moisture than the 3D control. An increase in alkyl chain provides additional resistance. FIG. 11C shows XRD pattern of 3D and 3D/2D perovskite films on glass stored in the humidity chamber. The 3D control showed severe decomposition of the perovskite into PbI₂ and δ-phase perovskite on day 3, whereas 3D/2D perovskites showed no sign of δ-phase.

FIG. 12 shows certification of 3D/2D PSC with stabilized J-V curve tested at an independent and accredited PV testing lab (Newport).

FIGS. 13A-13C show extended stabilization measurement and MPP measurement on 3D/2D PSCs. FIG. 13A shows 3D/2D PSC device results on the same pad on two consecutive days (measurement at Newport). The 3D/2D PSC shows almost identical results even after extensive stabilization measurement (˜40 min on day 1 and ˜31 min on day 2) demonstrating remarkable operational stability. FIG. 13B shows the MPP was measured under full solar illumination (AM 1.5 G, 100 mW/cm²) without a UV-filter. The PSC shows an initial PCE of 22.3% and maintains a PCE >20% over 200 hrs. FIG. 13C shows the MPP was measured under full solar illumination (AM 1.5G, 100 mW/cm²) without a UV-filter. The PSC shows an initial PCE of 22.3% and maintains a PCE >20% over 500 hrs.

FIGS. 14A-14B show absorption spectrum and EQE spectrum of the PSCs. FIGS. 14A and 14B show Tauc plot from UV-Vis absorption spectrum (a) and external quantum efficiency (EQE) plot (FIG. 14B) used to determine the bandgap. Bandgap determined from tangent line from UV-Vis tauc plot is ˜1.56 eV and from the EQE plot is ˜1.55 eV. The bandgap determined from EQE onset is ˜1.53 eV. The integrated current density determined from the EQE spectrum is also shown in FIG. 14B.

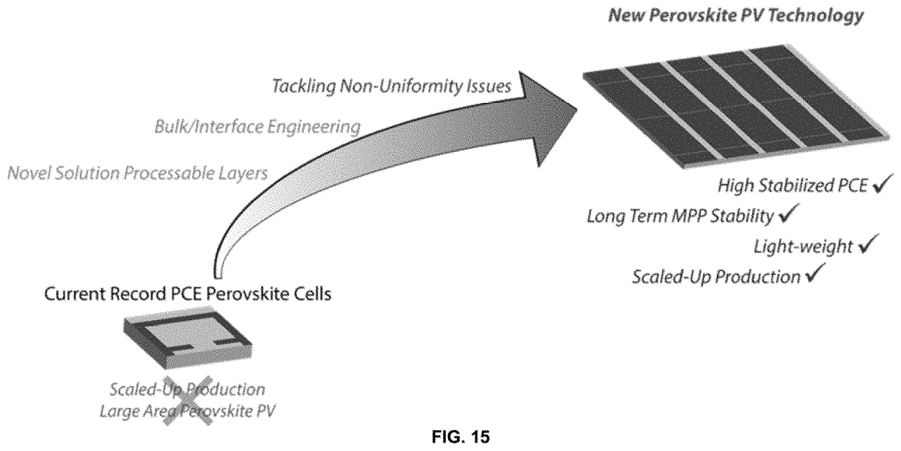

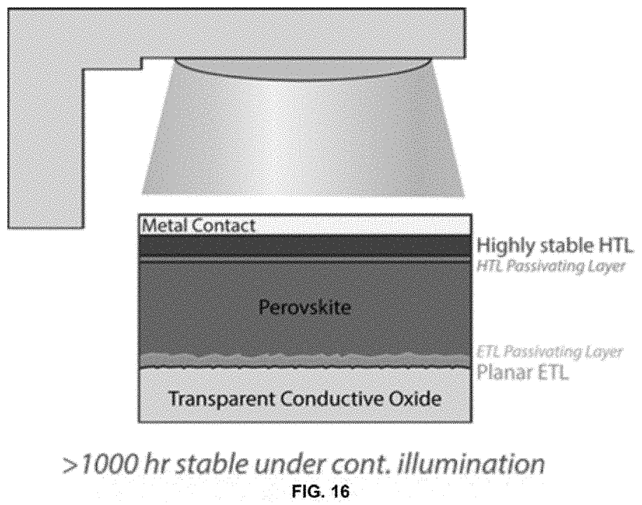

FIGS. 15 and 16 shows a perovskite based photovoltaic.

A method of manufacturing a photovoltaic device structure can include coating a perovskite precursor in a solvent on a semiconductor substrate, the precursor forming a layer on surface of the semiconductor substrate. In certain circumstances, the precursor is deposited on an underlying perovskite structure. The resulting photovoltaic device can include a hole transport layer adjacent to a first electrode, an electron transport layer adjacent to a second electrode, a perovskite layer between the hole transport layer and the electron transport layer, and a passivating layer between the perovskite layer and the hole transporting layer. The passivating layer can include a 2D perovskite layer.

In certain circumstances, coating method can include spin-coating, ink-jet printing, roll-to-roll printing, or blade coating. Spin coating together with selection of solvent can effectively passivate interface defects. This can lead to selective precursor dissolution, in which solvent used for the 2D perovskite deposition selectively dissolves a 2D perovskite precursor, while retaining a high quality 3D perovskite underlayer. In certain circumstances, coating can include spin coating at a rate between 2000 and 6000 rpm, for example, at 2000, 2500, 3000, 3500, 4000, 4500, 5000, 5500, or 6000 rpm. The solvent can be a halogenated hydrocarbon, for example, a chlorinated hydrogenated hydrocarbon such as chloroform (CHCl₃).

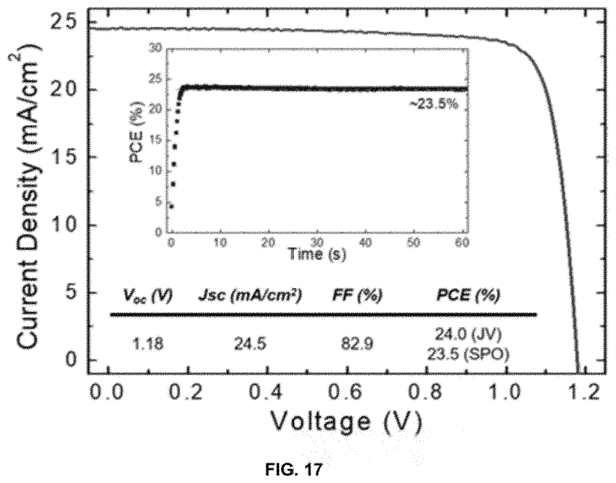

Performance factors of a high performance device are shown in FIG. 17. The device was prepared using the criteria described above, but the passivation layer was applied at a spin coating rate of 3000 rpm instead of 5000 rpm.

In certain circumstances, the perovskite can include a C2-C16 alkyl ammonium can be n-Butylammonium bromide (C₄Br), n-Hexylammonium bromide (C₆Br), or n-Octylammonium bromide (C₈Br). The solvent can be chloroform. The 2D perovskite can be lead iodide.

In certain circumstances, the 2D perovskite layer can include a C2-C16 alkyl ammonium group.

In certain circumstances, the device can be made by a method described herein.

In certain circumstances, the device can have a power conversion efficiency of over 23%.

The perovskite material can have the formula (I)

A′(Pb:B′)X₃ (I)

where A′ is an organic or large inorganic cation, B′ is a divalent metal cation or missing (such as Co²⁻, Cu²⁺, Fe²⁺, Mg²⁺, Mn²⁺, Ni²⁺, Sn²⁺, Sr²⁺, or Zn²⁺), X is a halide ion (such as I⁻, Br⁻, or Cl⁻). The B′ can replace 0.5% to 50%, 0.75% to 40%, 1% to 30%, or about 1% to 25% of the Pb in the composition. For example, a perovskite can include methylammonium lead triiodide (MAPbI₃) perovskite where a portion of the Pb content is replaced with various alternative divalent metal species, such as Co, Cu, Fe, Mg, Mn, Ni, Sn, Sr, and Zn.

The large inorganic cation can be an alkyl ammonium, for example, a C2-C16 alkyl ammonium halide, for example, a C2 alkyl ammonium, C3 alkyl ammonium, C4 alkyl ammonium, C5 alkyl ammonium, C6 alkyl ammonium, C7 alkyl ammonium, C8 alkyl ammonium, C10 alkyl ammonium, C12 alkyl ammonium, C14 alkyl ammonium, or C16 alkyl ammonium halide.

Details of one or more embodiments are set forth in the accompanying drawings and description. Other features, objects, and advantages will be apparent from the description, drawings, and claims. Although a number of embodiments of the invention have been described, it will be understood that various modifications may be made without departing from the spirit and scope of the invention. It should also be understood that the appended drawings are not necessarily to scale, presenting a somewhat simplified representation of various features and basic principles of the invention.

What is claimed is:

1. A method of manufacturing a photovoltaic device structure comprising:
coating a perovskite precursor in a solvent on a semiconductor substrate, the precursor forming a layer on surface of the semiconductor substrate.

2. The method of claim 1, wherein the layer is a 2D perovskite layer.

3. The method of claim 1, wherein the semiconductor includes a 3D perovskite on an electrode layer.

4. The method of claim 1, wherein the precursor includes a C2-C16 alkyl ammonium halide.

5. The method of claim 4, wherein the C2-C16 alkyl ammonium is a C4 alkyl ammonium, C5 alkyl ammonium, C6 alkyl ammonium, C7 alkyl ammonium, C8 alkyl ammonium, C10 alkyl ammonium, C12 alkyl ammonium, C14 alkyl ammonium, or C16 alkyl ammonium.

6. The method of claim 4, wherein the halide is a bromide or iodide.

7. The method of claim 1, wherein the perovskite precursor includes a lead iodide.

8. The method of claim 1, wherein the solvent is chloroform.

9. The method of claim 1, wherein coating includes spin-coating, ink-jet printing, roll-to-roll printing, or blade coating.

10. The method of claim 1, wherein the C2-C16 alkyl ammonium is n-Butylammonium bromide (C₄Br), n-Hexylammonium bromide (C₆Br), or n-Octylammonium bromide (C₈Br), the solvent is chloroform and the 2D perovskite is lead iodide.

11. The method of claim 1, wherein coating includes spin coating at a rate between 2000 and 6000 rpm.

12. A photovoltaic device comprising:
a hole transport layer adjacent to a first electrode;
an electron transport layer adjacent to a second electrode;
a perovskite layer between the hole transport layer and the electron transport layer; and
a passivating layer between the perovskite layer and the hole transporting layer.

13. The device of claim 12, wherein the passivating layer includes a 2D perovskite layer.

14. The device of claim 13, wherein the 2D perovskite layer includes a C2-C16 alkyl ammonium group.

15. The device of claim 12, wherein the device is made by a method of any of claims 1-10.

16. The device of claim 12, wherein the device has a power conversion efficiency of over 23%.

17. The device of claim 12, wherein the perovskite layer includes a material having the formula (I)
A′(Pb:B′)X₃ (I)
where A′ is an organic or large inorganic cation, B′ is a divalent metal cation or missing, and X is a halide ion.

18. The device of claim 17, wherein the large inorganic cation is a C2-C16 alkyl ammonium halide.
